(19) United States
(12) Patent Application Publication
(10) Pub. No.: US 2010/0019373 A1
(43) Pub. Date: Jan. 28, 2010

(54) UNIVERSAL SUBSTRATE FOR SEMICONDUCTOR PACKAGES AND THE PACKAGES

(75) Inventor: Wen-Jeng FAN, Hsinchu (TW)

Correspondence Address: Muncy, Geissler, Olds & Lowe, PLLC, P.O. BOX 1364, FAIRFAX, VA, 22038-1364, US

(73) Assignee: POWERTECH TECHNOLOGY INC.

(21) Appl. No.: 12/178,098

(22) Filed: Jul. 23, 2008

(51) Int. Cl. H01L 23/52; H05K 1/03

(52) U.S. Cl. 257/691; 174/255; 257/E23.079

(57) ABSTRACT

A universal substrate for semiconductor packages and the package are revealed. The universal substrate comprises a substrate core, two peripheral rows of bonding fingers and a central row of redistribution fingers disposed on the substrate core, and a solder mask formed on the substrate core. The redistribution fingers are located between two rows of the bonding fingers. The solder mask has an opening to expose the redistribution fingers. A plurality of exhaust grooves are formed on the solder mask without penetrating through the solder mask where one end of the exhaust grooves connects to the opening and the other end extends toward the edges of the substrate core without connecting to another opening exposing the bonding fingers to be the releasing channels of gases generated during die-attaching processes. When disposing larger IC chips, the issue of residue bubbles trapped in the covered opening and the issue of contaminations of bonding fingers by the die-bonding adhesives can be eliminated. In one of the embodiment, the traces connecting to the redistribution fingers can be overlapped with the exhaust grooves without being exposed from the solder mask to enhance the design flexibility of the exhaust grooves.

### FIELD OF THE INVENTION

The present invention relates to a printed wiring board for semiconductor packages, especially to a universal substrate for semiconductor packages and the packages.

### BACKGROUND OF THE INVENTION

In the conventional semiconductor packages such as Ball Grid Array (BGA) packages or card-type semiconductor packages, substrates such as printed wiring boards are used to carry IC chips and to electrically connect the bonding fingers of the substrates to the bonding pads of the IC chips to form electrical interconnections. For standard packages, the dimensions of the semiconductor packages, especially the memory cards, can not be changed in accord with the specifications. In order to have different memory capacities, at least a row of redistribution fingers is disposed at different locations on the substrate surface to make the substrate universal to accommodate IC chips with different dimensions to reduce the manufacturing cost of the substrates. However, when attaching IC chips with larger dimensions, the redistribution fingers become useless and covered by a die-bonding adhesive where gases generated during die-attaching processes are easily trapped between the redistribution fingers leading to popcorn in the following processes or in applications.

As shown in FIG. 1A and FIG. 1B, a conventional semiconductor package comprises a universal substrate 100, a chip 11, a die-bonding adhesive 12, a plurality of first bonding wires 13, a plurality of second bonding wires 14, and an encapsulant 15. The substrate 100 primarily has a substrate core 110 and a solder mask 130 where the substrate core 110 has a surface 111 on which a first row of bonding fingers 121, a second row of bonding fingers 122, and a third row of bonding fingers 123 are disposed. The second row of bonding fingers 122 and the third row of bonding fingers 123 are conventional bonding fingers located at two corresponding edges of the surface 111 for electrical connections of IC chips with larger dimensions. The first row of bonding fingers 121 are located between the second row of bonding fingers 122 and the third row of bonding fingers 123 as the redistribution fingers for electrical connections of IC chips with smaller dimensions. The solder mask 130 is formed on the surface 111 with a plurality of openings 131, 132, and 133 to individually expose the first row of bonding fingers 121, the second row of bonding fingers 122, and the third row of bonding fingers 123. When the chip 11 is a large chip, the chip 11 is disposed on the substrate 100 with the die-bonding adhesive 12 covering the first row of bonding fingers 121. The chip 11 is electrically connected to the second row of bonding fingers 122 of the substrate 100 by the first bonding wires 13, moreover, the chip 11 is also electrically connected to the third row of bonding fingers 123 of the substrate 100 by the second bonding wires 14. The encapsulant 15 is formed on the solder mask 130 of the substrate 100 to encapsulate the chip 11, the first bonding wires 13, and the second bonding wires 14. As shown in FIG. 1B, the back surface of the chip 11 is attached to the solder mask 130 of the substrate 100 by the die-bonding adhesive 12 where the die-bonding adhesive 12 fills the opening 131. Since the opening 131 of the solder mask 130 is a closed opening and is covered by the chip 11, as shown in FIG. 1A, so that the residue gases generated during die-attaching processes can not easily be released which become bubbles 12A trapped in the die-bonding adhesive 12 leading to popcorn in the following processes or in applications.

In order to avoid the formation of residue bubbles during die-attaching processes, a substrate with interconnected openings of solder mask is used as a chip carrier. A prior-art semiconductor package having a universal substrate is revealed by Chang et al. in R.O.C. Taiwan patent No. I281733. The prior-art semiconductor package is similar to the structure as shown in FIG. 2A and FIG. 2B. Even though the residue bubbles can be avoided, but the die-bonding adhesive easily bleeds to the bonding fingers located at two corresponding edges of the substrate leading to contaminations of bonding fingers and unwanted plating on the exposed traces from the substrate.

As shown in FIG. 2A and FIG. 2B, the conventional semiconductor package comprises a universal substrate 200, a chip 21, a die-bonding adhesive 22, a plurality of first bonding wires 23, a plurality of bonding wires 24, and an encapsulant 25. The substrate 200 primarily has a substrate core 210, a first row of bonding fingers 221, a second row of bonding fingers 222, a third row of bonding fingers 223, and a solder mask 230 disposed on a surface 211 of the substrate 210. Furthermore, the first row of bonding fingers 221 are located between the second row of bonding fingers 222 and the third row of bonding fingers 223. The solder mask 230 is formed on the surface 211 with a plurality of openings 231, 232, and 233 to individually expose the first row of bonding fingers 221, the second row of bonding fingers 222, and the third row of bonding fingers 223. The solder mask 230 further has a plurality of extended openings 235 externally extending from the central opening 231 to connect to the peripheral opening 232 or 233 of the substrate 200. The extended openings 235 penetrate through the solder mask 230 until exposing the surface 211 of the substrate 210. The chip 21 is attached to the substrate 200 by the die-bonding adhesive 22. When the chip 21 is a larger chip, the chip 21 covers the opening 231 and the first row of bonding fingers 221. The chip 21 is electrically connected to the second row of bonding fingers 222 of the substrate 200 by the first bonding wires 23 and the chip 21 is also electrically connected to the third row of bonding fingers 223 of the substrate 200 by the second bonding wires 24. An encapsulant 25 is formed on the solder mask 230 of the substrate 200 to encapsulate the chip 21, the first bonding wires 23, and the second bonding wires 24. As shown in FIG. 2A and FIG. 2B, the die-bonding adhesive 22 fills the opening 231 where the residue bubbles of the opening 231 can be released through the extended openings 235. However, during die-attaching processes, the die-bonding adhesive 22 becomes flowing under high temperatures and high pressures, the die-bonding adhesive 22 may flow into the peripheral openings 232 and 233 of the substrate 200 through the extended opening 235 causing bleeding 22A leading to contaminations of the second row of bonding fingers 222 or/and the third row of bonding fingers 223, as shown in FIG. 2B. The first bonding wires 23 or the second bonding wires 24 can not be bonded on the second row of bonding fingers 222 or the third row of bonding fingers 223 unless a thick plated layer 280 is disposed on the surfaces of the first row of bonding fingers 221, the second row of bonding fingers 222, and the third row of bonding fingers 223 by plating processes. The manufacturing cost is increased.

Furthermore, in order to make the first row of bonding fingers 221 having the function of redistribution fingers, the substrate 200 further comprises a plurality of traces 250 connecting the first row of bonding fingers 221 with the second row of bonding fingers 222. Since the extended openings 235 penetrate through the solder mask 230, once the traces 250 are crossed with the extended opening 235, the crossed portions of the traces 250 are exposed from the solder mask 230. During the formation the thick plated layers 280, the exposed traces 250 are also plated in the extended openings 235. The trapped bubbles are hindered from leaving the extended opening 235. The bubble-releasing function is weakened.

### SUMMARY OF THE INVENTION

The main purpose of the present invention is to provide a universal substrate for semiconductor packages and the packages to provide bubble-releasing channels to avoid trapped bubbles and to effectively eliminate bleeding issues during die-attaching processes.

According to the present invention, a universal substrate for semiconductor packages primarily comprises a substrate core, a first row of bonding fingers, a second row of bonding fingers, a third row of bonding fingers, and a solder mask. The substrate has a surface where the first row of bonding fingers, the second row of bonding fingers, and the third row of bonding fingers are disposed on the surface of the substrate. The first row of bonding fingers are located between the second row of bonding fingers and the third row of bonding fingers. The solder mask is formed on the surface of the substrate core where the solder mask has a first opening, a second opening, and a third opening to individually expose the first row of bonding fingers, the second row of bonding fingers, and the third row of bonding fingers. The solder mask further has a plurality of first exhaust grooves formed on an exposed surface of the solder mask without penetrating through the solder mask. Moreover, one end of the first exhaust grooves connects the first opening and the other end extends toward a plurality of edges of the surface of the substrate core without connecting to the second opening nor to the third opening.

According to the present invention, a semiconductor package using the universal substrate mentioned above for packaging large IC chips primarily comprises the universal substrate, a chip with a larger dimension, a die-bonding adhesive, a plurality of first bonding wires, and a plurality of second bonding wires. The chip is disposed on the universal substrate to cover the first row of bonding fingers and the first opening where the chip has a plurality of first bonding pads and a plurality of second bonding pads. The die-bonding adhesive fixes the back surface of the chip to the solder mask of the universal substrate where the die-bonding adhesive fills the first opening and the first exhaust grooves. The first bonding pads of the chip are electrically connected to the second row of bonding fingers of the universal substrate by the first bonding wires. The second bonding pads of the chip are electrically connected to the third row of bonding fingers of the universal substrate by the second bonding wires.

According to the present invention, another semiconductor package using the universal substrate mentioned above for packaging small IC chips primarily comprises a above-mentioned universal substrate, a chip with a smaller dimension, a die-bonding adhesive, a plurality of first bonding wires, and a plurality of second bonding wires. The chip is disposed on the universal substrate located between the first row of bonding fingers and the third row of bonding fingers where the chip has a plurality of first bonding pads and a plurality of second bonding pads. The die-bonding adhesive fixes the back surface of the chip to the solder mask of the universal substrate where the die-bonding adhesive only fills the first exhaust grooves. The first bonding pads of the chip are electrically connected to the first row of bonding fingers of the universal substrate by the first bonding wires. The second bonding pads of the chip are electrically connected to the third row of bonding fingers of the universal substrate by the second bonding wires.

According to the present invention mentioned above, the universal substrate for semiconductor packages and the package have the following effects and advantages:

1. The exhaust grooves formed on the solder mask of the universal substrate without penetrating through the solder mask can effectively provide gas-releasing channels from covered opening during die-attaching processes without any bubbles trapped in the die-bonding adhesive.

2. The traces connecting redistribution fingers, i.e., the first row of bonding fingers, are not exposed from the exhaust grooves on the solder mask to reduce the plating area with lower plating costs and to avoid hindrance of unwanted plated layers inside the exhaust grooves to release residue gases. Furthermore, the unexposed traces can be crossed with the exhaust grooves to increase the design flexibility of the exhaust grooves.

3. The bleeding area of the die-bonding adhesive is constrained by the extended end of the exhaust grooves. Moreover, the exhaust grooves do not connect to the peripheral openings of the solder mask so that the bleeding of the die-bonding adhesive does not contaminate the second row of bonding fingers nor the third row of bonding fingers to effectively eliminate the bleeding of the die-bonding adhesive of the conventional semiconductor packages during die-attaching processes of large IC chips.

4. The universal substrate can be configured for packaging different dimensions of IC chips by using the design of the first row of bonding fingers, the second row of bonding fingers, and the third row of bonding fingers to save the manufacturing cost of the substrate.

5. Small IC chips can be electrically connected to the universal substrate by wire-bonding on the first row (central row) of bonding fingers since the traces connecting between the first row of bonding fingers and the second row (peripheral row) of bonding fingers. The lengths of the bonding wires can be shortened without actually wire-bonding to the second row of bonding fingers.

### DESCRIPTION OF THE DRAWINGS

FIGS. 1A and 1B show an unencapsulated top view and a cross-sectional view of a conventional semiconductor package.

FIGS. 2A and 2B show an unencapsulated top view and a cross-sectional view of another conventional semiconductor package.

FIGS. 3A, 3B, and 3C show a top view, a cross-sectional view, and a three-dimensional view of a universal substrate of a semiconductor package according to the first embodiment of the present invention.

FIG. 4A shows a top view of a universal substrate of a semiconductor package after attaching a large IC chip according to the first embodiment of the present invention.

FIG. 4B shows a cross-sectional view of a semiconductor package including the universal substrate and a large IC chip according to the first embodiment of the present invention.

FIG. 5A shows a top view of a universal substrate of a semiconductor package after attaching a small IC chip and a dummy chip according to the first embodiment of the present invention.

FIG. 5B shows a cross-sectional view of a semiconductor package including the universal substrate, a small IC chip, and a dummy chip according to the first embodiment of the present invention.

FIGS. 6A and 6B show a top view and a cross-sectional view of a universal substrate of a semiconductor package according to the second embodiment of the present invention.

FIG. 7 shows a top view of another universal substrate of a semiconductor package according to the third embodiment of the present invention.

FIG. 8 shows a top view of another universal substrate of a semiconductor package according to the fourth embodiment of the present invention.

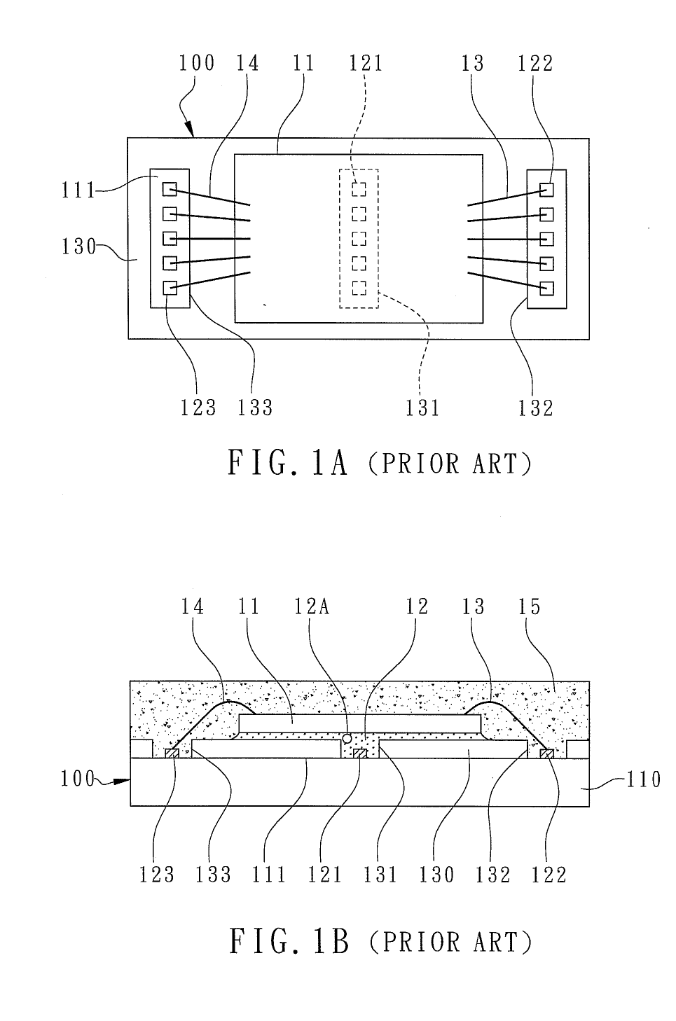

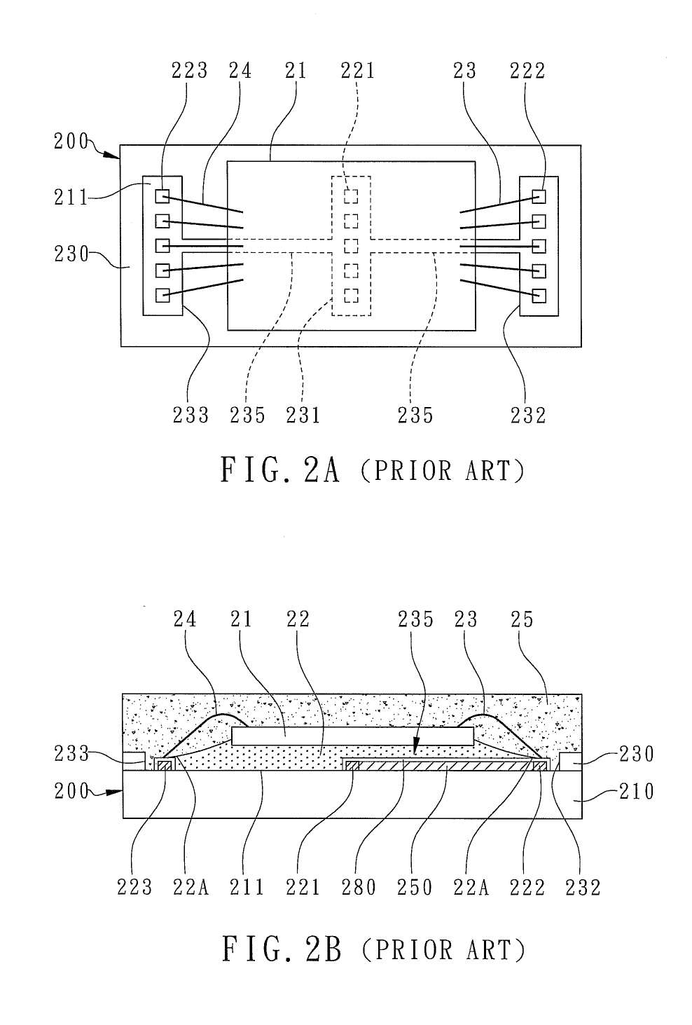

### DETAIL DESCRIPTION OF THE INVENTION

Please refer to the attached drawings, the present invention is described by means of embodiments below.

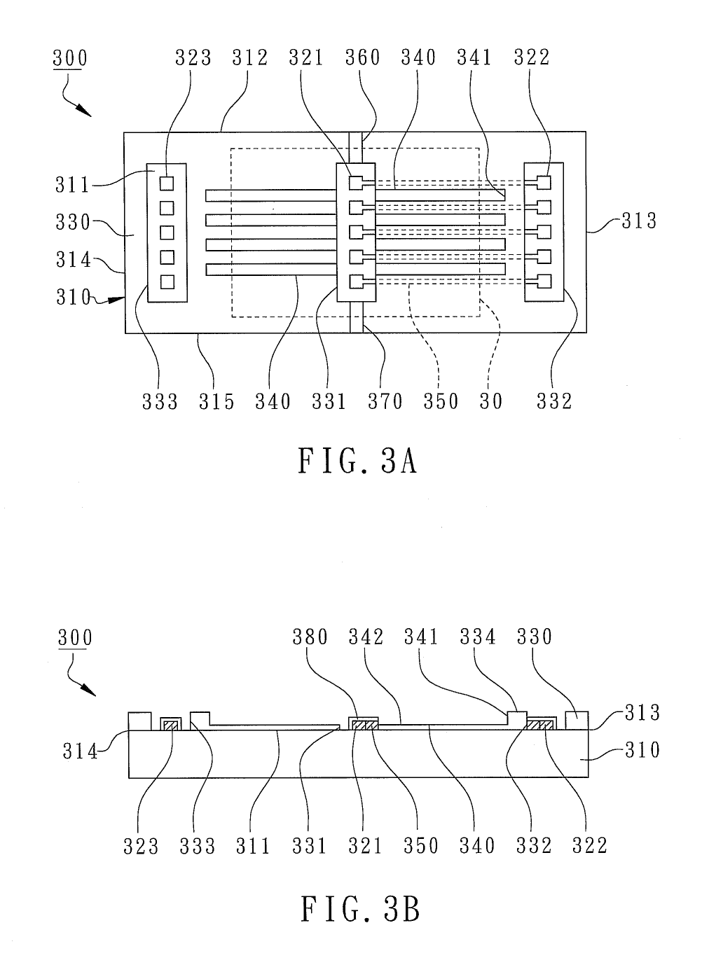

According to the first embodiment of the present invention, a universal substrate for semiconductor packages is described in the top view of FIG. 3A, in the cross-sectional view of FIG. 3B, and in the three-dimensional view of FIG. 3C. The universal substrate 300 primarily comprises a substrate core 310, a first row of bonding fingers 321, a second row of bonding fingers 322, a third row of bonding fingers 323, and a solder mask 330. As shown in FIG. 3A, the substrate core 310 has a surface 311 as an internal surface for attaching IC chips. The surface 311 has a first edge 312, a second edge 313, a third edge 314, and a fourth edge 315. In the present embodiment, the second edge 313 and the third edge 314 are parallel to each other and the first edge 312 and the fourth edge 315 are also parallel to each other. The first edge 312 connects to the second edge 313 and to the third edge 314. The fourth edge 315 also connects to the second edge 313 and to the third edge 314.

As shown in FIG. 3A, the first row of bonding fingers 321, the second row of bonding fingers 322, and the third row of bonding fingers 323 are disposed on the surface 311 of the substrate core 310. It is easy to be understood that the row number of bonding is not limited to be three as shown in the figures which can be increased or decreased according to the actual design and layout. Moreover, the first row of bonding fingers 321 are located between the second row of bonding fingers 322 and the third row of bonding fingers 323. In the present embodiment, the second row of bonding fingers 322 and the third row of bonding fingers 323 are peripheral bonding fingers and the first row of bonding fingers 321 are redistribution fingers and are electrically connected to the second row of bonding fingers 323 by a plurality of traces 350. The first row of bonding fingers 321 are disposed at the central area of the surface 311. The second row of bonding fingers 322 are disposed adjacent the second edge 313 of the surface 311 of the substrate core 310 and the third row of bonding fingers 323 adjacent to the third edge 314 of the surface 311 of the substrate core 310. The first row of bonding fingers 321, the second row of bonding fingers 322, and the third row of bonding fingers 323 are configured for wire-bonding connections. The materials of the first row of bonding fingers 321, the second row of bonding fingers 322, and the third row of bonding fingers 323 can be copper. In the present embodiment, a plated layers 380 is plated on the surfaces of the bonding fingers 321, 322, and 323 to enhance the bonding strengths and electrical connections of the bonding wires in the semiconductor packages. The material of the plated layer 380 can be chosen from a group of silver, nickel-gold, tin, nickel-palladium-gold, tin-lead, tin-bismuth.

As shown in FIG. 3A, 3B, and 3C, the solder mask 330 is formed on the surface 311 of the substrate core 310 where the solder mask 330 has a first opening 331 to expose the first row of bonding fingers 321. As shown in FIG. 3A, the solder mask 330 further has a second opening 322 and a third opening 323 to individually expose the second row of bonding fingers 322 and the third row of bonding fingers 323 where the second opening 332 and the third opening 333 can be closed openings or open-loop openings. In the present embodiment, the second opening 332 and the third opening 333 are closed openings adjacent to the second edge 313 and to the third edge 314. The solder mask 330 can be chosen from either cover layer or liquid photo imagable solder mask. The patterns of the solder mask 330 can be formed by film lamination or printing followed by exposure and development.

As shown in FIG. 3A and 3B, a plurality of first exhaust grooves 340 are formed on an exposed surface 334 of the solder mask 330 without penetrating through the solder mask 330. One end of the first exhaust grooves 340 connects to the first opening 331 and the other end of the first exhaust grooves 340 extends toward the edges of the surface 311 of the substrate core 310, i.e., the second edge 313 and the third edge 314 without connecting to the second opening 332 nor to the third opening 333. It is normal but not limited that the first exhaust grooves 340 are formed by laser burning so that the depth of the exhaust grooves 340 can be well controlled without penetrating through the solder mask 330 to avoid the exposure of the traces 350 and the surface 311. As shown in FIG. 3A, the first exhaust grooves 340 do not connect to the second opening 332 nor to the third opening 333 to avoid bleeding of the die-bonding adhesive to contaminate the second row of bonding fingers 322 and the third row of bonding fingers 323. In the present embodiment, the first exhaust grooves 340 are linear. One end of the exhaust groove 340 connects to two longer sides of the first opening 331. The extended end 341 of the exhaust grooves 340 extends beyond the die-bonding area of the large IC chip 30 so that the gases generated during die-attaching processes can be released through the first exhaust grooves 340 without remaining under the large IC chip 30. To be more specific, the extended end 341 of the first exhaust grooves 340 includes a plurality of closed slot terminals disposed in the solder mask 330 to restrict the bleeding area of the die-bonding adhesive.

Furthermore, the universal substrate 300 further comprises a plurality of traces 350 formed on the surface 311 of the substrate 310. The traces 350 connect the first row of bonding fingers 321 to the second row of bonding fingers 322 where the solder mask 330 further covers the traces 350 so that the first row of bonding fingers 321 become the redistribution fingers connected with the second row of bonding fingers 322. As shown in FIG. 3B, the traces 350, the first row of bonding fingers 321, the second row of bonding fingers 322, and the third row of bonding fingers 323 are formed in the same metal wiring layer. Therefore, large IC chips can be electrically connected to the universal substrate 300 by the second row of bonding fingers 322, moreover, small IC chips also can be electrically connected to the universal substrate 300 by the first row of bonding fingers 321 to further reduce the lengths of the bonding wires. Therefore, the universal substrate 300 can package different dimensions of IC chips to reduce the manufacturing cost of the substrates. Furthermore, since the traces 350 are covered by the solder mask 330 so that the traces 350 are not exposed from the first exhaust grooves 340 nor forming unwanted plating layers 380 inside the exhaust grooves 340. Therefore, the plated area is reduced leading to lower plating costs and the first exhaust grooves 340 are not hindered by the unwanted plated material inside.

As shown in FIG. 3A, in the present embodiment, the first exhaust grooves 340 can be arranged to be staggeredly dislocated with the traces 350 without overlapping so that the first exhaust grooves 340 are not crossed with the traces 350. Accordingly, the depths of the first exhaust grooves 340 can be increased without exposing the traces 350. As shown in FIG. 3B, the solder mask 330 has a non-penetrated thickness from the bottom surface 342 of the first exhaust grooves 340 to the surface 311 of the substrate core 310 not greater than the thickness of the traces 350 so that the gases generated during die-attaching processes can easily be released through the exhaust grooves 340. To be more specific, at least a second exhaust groove 360 connects to the first opening 331 and extends to the first edge 312 of the surface 311 of the substrate core 310 to enhance the gas-releasing functions. The connections of the first opening 331 to the second exhaust groove 360 are located at one of the shorter sides of the first opening 331 adjacent to the first edge 312. The entended end of the second exhaust groove 360 is connected to the first edge 312. At least a third exhaust groove 370 connects to the first opening 331 and extends to the fourth edge 315 of the surface 311 of the substrate core 310.

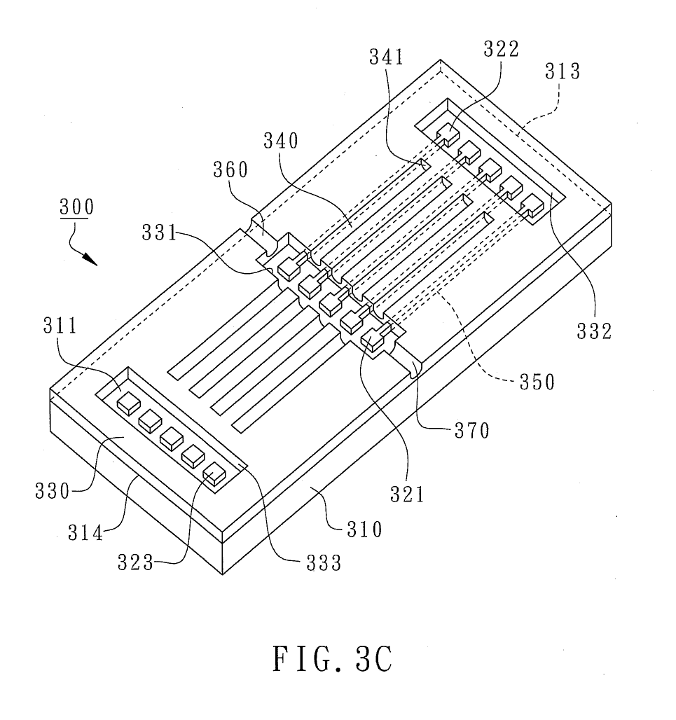

The above-mentioned universal substrate 300 can be used to package large IC chips to be a semiconductor package such as memory cards, BGA (Ball Grid Array), or LGA (Land Grid Array). The universal substrate 300 after attaching a large IC chip is shown in FIG. 4A. A semiconductor package comprising the universal substrate 300 and a large IC chip is shown in FIG. 4B.

The semiconductor package primarily comprises the above-mentioned universal substrate 300, a large IC chip 30, a die-bonding adhesive 41, a plurality of first bonding wires 42, and a plurality of second bonding wires 43. The large IC chip 30 having a larger memory capacity is disposed on the universal substrate 300. The large IC chip 30 has a plurality of first bonding pads 31 and a plurality of second bonding pads 32 formed on the active surface 33 of the large IC chip 30 as the external electrical electrodes. After die attachment, the large IC chip 30 on the universal substrate 300 covers the first row of bonding fingers 321 and the first opening 331 where the first bonding pads 31 are adjacent to the second row of bonding fingers 322 and the second bonding pads 32 are adjacent to the third row of bonding fingers 323. The extended ends 341 of the first exhaust grooves 340 are located beyond the large IC chip 30. Normally, the material of the die-bonding adhesive 41 is chosen from epoxy or B-stage adhesive materials which become flowing after heating. The back surface 34 of the large IC chip 30 is attached to the solder mask 330 of the universal substrate 300 by the die-bonding adhesive 41, moreover, the die-bonding adhesive 41 further fills the first opening 331 and some sections of the first exhaust grooves 340 to increase adhesion strengths.

As shown in FIG. 4B again, the first bonding pads 31 of the large IC chip 30 are electrically connected to the second row of bonding fingers 322 by the first bonding wires 42 and the second bonding pads 32 of the large IC chip 30 are electrically connected to the third row of bonding fingers 323 of the universal substrate 300 by the second bonding wires 43.

As shown in FIG. 4B again, the semiconductor package further comprises an encapsulant 44 formed on the universal substrate 300 to encapsulate the large IC chip 30, the first bonding wires 42, and the second bonding wires 43 where the die-bonding adhesive 41 fills the section of the exhaust grooves 340 around the large IC chip 30 and the encapsulant 44 fills the other section of the exhaust grooves 340 away from the large IC chip 30. The encapsulant 44 is an EMC (Epoxy molding Compound).

During the die-attaching processes, the large IC chip 30 is pressed down toward the universal substrate 300 to squeeze out the uncured and flowing die-bonding adhesive 41. The gases can be released through the first exhaust grooves 340 to avoid bubbles trapped inside the first opening 331. Moreover, the adhesion strength can be enhanced by filling the die-bonding adhesive 41 into the first opening 331 and the first exhaust grooves 340. The extended ends 341 of the first exhaust grooves 340 can effectively guide the bleeding of the die-bonding adhesive 41 without flowing to the second opening 332 and to the third opening 333 to avoid contaminations of the second row of bonding fingers 322 and the third row of bonding fingers 323.

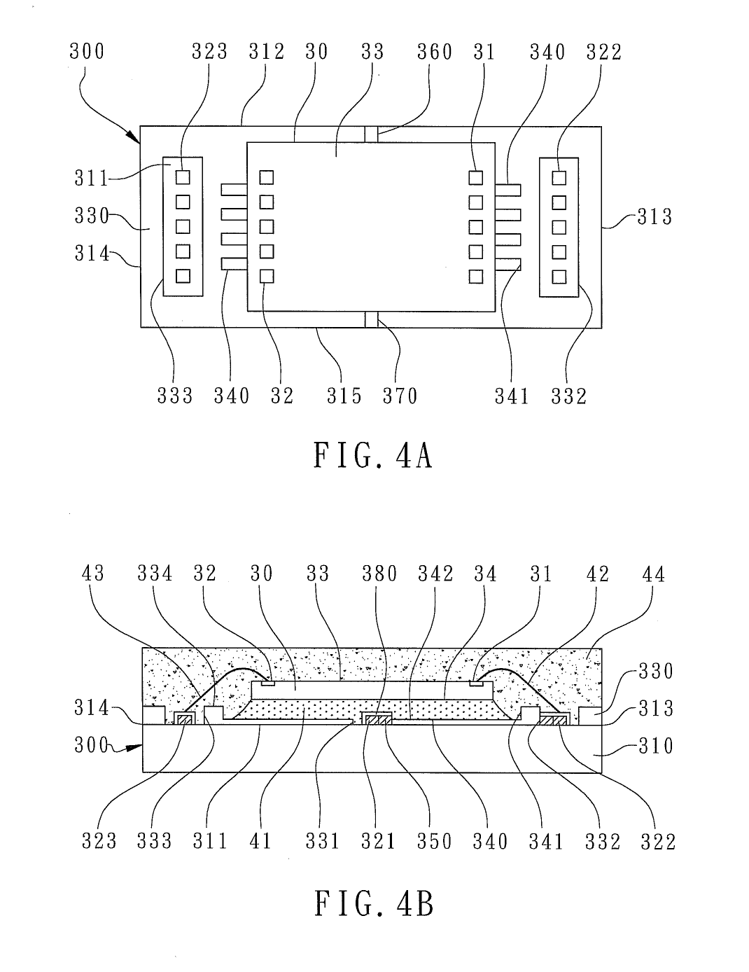

Small IC chips can also be packaged in the above-mentioned universal substrate 300 to be semiconductor packages. A small IC chip disposed on the universal substrate 300 is described in the top view of FIG. 5A and a semiconductor package comprised the universal substrate 300 and the small IC chip is described in the cross-sectional view of FIG. 5B.

The semiconductor package primarily comprises the above-mentioned universal substrate 300, a small IC chip 50, a die-bonding adhesive 61, a plurality of first bonding wires 62, and a plurality of second bonding wires 63. The small IC chip 50 having a smaller memory capacity is disposed on the universal substrate 300 with half or less of the dimension of the large IC chip 30. The small IC chip 50 is disposed between the first row of bonding fingers 321 and the third row of bonding fingers 323 where the small IC chip 50 has a plurality of first bonding pads 51 and the second bonding pads 52 formed on the active surface 53 of the small IC chip 50. After die-attaching processes, the small IC chip 50 disposed on the universal substrate 300 does not cover the first row of bonding fingers 321 nor the first opening 331. The first bonding pads 51 are adjacent to the first row of bonding fingers 321 and the second bonding pads 52 are adjacent to the third row of bonding fingers 323.

As shown in FIG. 5B, the back surface 54 of the small IC chip 50 is attached to the solder mask 330 of the universal substrate 300 by the die-bonding adhesive 61 where the die-bonding adhesive 61 does not fill the first opening 331. The first bonding pads 51 of the small IC chip 50 are electrically connected to the first row of bonding fingers 321 of the universal substrate 300 by the first bonding wires 62 and the second bonding pads 52 of the small IC chip 50 are electrically connected to the third row of bonding fingers 323 of the universal substrate 300 by the second bonding wires 63.

As shown in FIG. 5B, an encapsulant 64 is formed on the universal substrate 300 to encapsulate the small IC chip 50, the first bonding wires 62, and the second bonding wires 63 where the die-bonding adhesive 61 fills the section of the first exhaust grooves 340 under the small IC chip 50 and the encapsulant fills the other section of the first exhaust grooves 340 away from the small IC chip 50.

As shown in FIG. 5B, preferably, the semiconductor package further comprises a dummy chip 70 with a dimension similar to the one of the small IC chip 50. The dummy chip 70 is disposed on the universal substrate 300 and located between the first row of bonding fingers 321 and the second row of bonding fingers 322 to balance the mold flow during encapsulation.

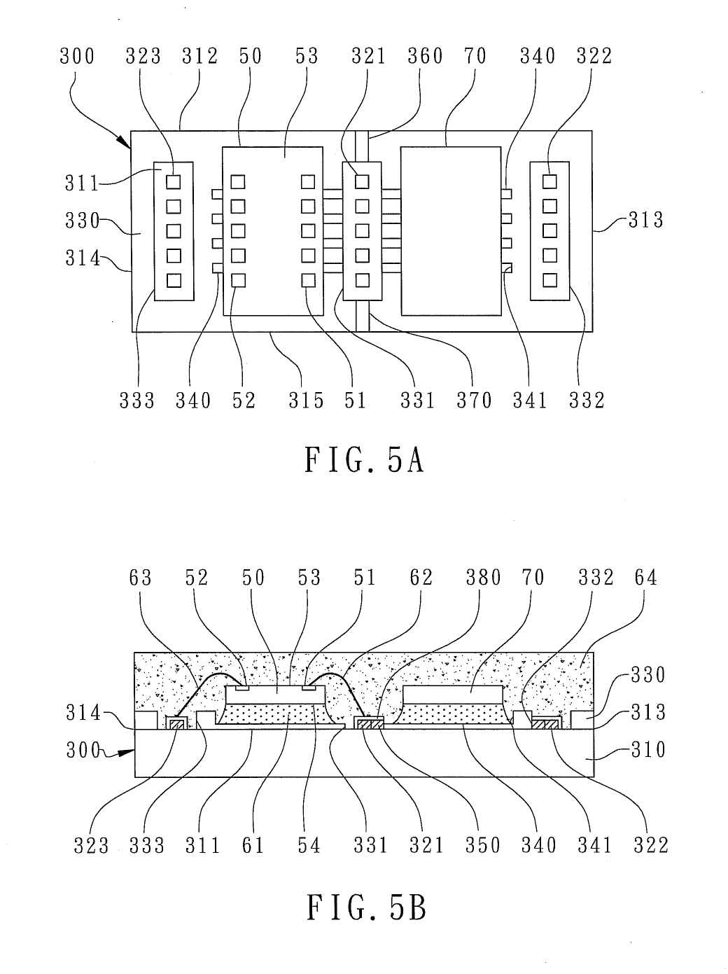

According to the second embodiment of the present invention, another universal substrate for semiconductor packages is described in the top view of FIG. 6A and the cross-sectional view of FIG. 6B. The basic structure and main components of the universal substrate 400 are the same as the ones mentioned in the first embodiment, therefore, the same components are described with the same figure numbers. The universal substrate 400 primarily comprises the substrate core 310, the first row of bonding fingers 321, the second row of bonding fingers 322, the third row of bonding fingers 323, and the solder mask 330. As shown in FIG. 6B, the first row of bonding fingers 321 is located between the second row of bonding fingers 322 and the third row of bonding fingers 323. The first opening 331 of the solder mask 330 exposes the first row of bonding fingers 321. The solder mask 330 further has a second opening 332 and a third opening 333 to individually expose the second row of bonding fingers 322 and the third row of bonding fingers 323. In the present embodiment, the second opening 332 and the third opening 333 are the open-loop peripheral openings which are individually connected to the second edge 313 and to the third edge 314. Similar to the first embodiment, the first exhaust grooves 340 are formed on the exposed surface 334 of the solder mask 330 without penetrating through the solder mask 330. One end of the first exhaust grooves 340 connects to the first opening 331 and the other end extends toward the edges of the surface 311 of the substrate core 310, i.e., the second edge 313 and the third edge 314, without connecting to the second opening 332 nor the third opening 333.

As shown in FIG. 6A, at least a connecting groove 490 is formed on the exposed surface 334 of the solder mask 330 and is crossed with the first exhaust grooves 340 to form as a gas-releasing net which can mutually release gases.

As shown in FIG. 6B, the universal substrate 400 further comprises the traces 350 formed on the surface 311 of the substrate core 310 and connect the first row of bonding fingers 321 with the second row of bonding fingers 322 where the solder mask 330 covers the traces 350. In the present embodiment, the solder mask 330 has a non-penetrated thickness from the bottom surface 442 of the first exhaust grooves 340 to the surface 311 of the substrate core 310 which is greater than the thickness of the traces 350. Therefore, at least one of the first exhaust grooves 340 is overlapped with at least one of the traces 350 without exposing the traces 350 to enhance the design flexibility of the first exhaust grooves 340. In the present embodiment, at least one of the first exhaust grooves 340 can completely overlap on one of the traces 350.

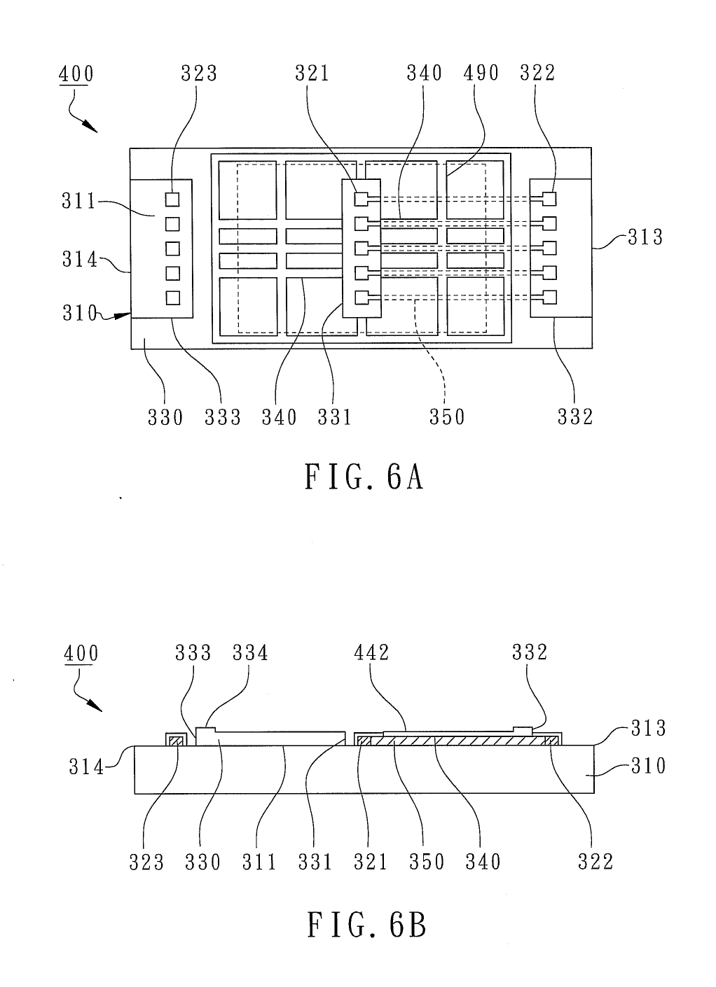

According to the third embodiment of the present invention, another universal substrate for semiconductor packages is described in the top view of FIG. 7. The basic structure and main components of the universal substrate 500 are similar to the ones mentioned in the first embodiment, therefore, the same components are described with the same figure numbers. The universal substrate 500 primarily comprises the substrate core 310, the first row of bonding fingers 321, the second bonding finger 322, the third row of bonding fingers 323, and the solder mask 330. The first opening 331 of the solder mask 330 exposes the first row of bonding fingers 321. The second opening 332 of the solder mask 330 exposes the second row of bonding fingers 322. The third opening 333 of the solder mask 330 exposes the third row of bonding fingers 323. Similarly, the first exhaust grooves 340 are formed on the exposed surface of the solder mask 330 without penetrating through the solder mask 330 where one end of the first exhaust grooves 340 connects to the first opening 331 and the other end extends toward the edges of the surface 311 of the substrate core 310, i.e., the second edge 313 and the third edge 314, without connecting to the second opening 332 nor to the third opening 333. In the present embodiment, the adjacent extended ends 541 of the first exhaust grooves 340 can connect to each other to form a U-shape channel of bleeding backflow. As shown in FIG. 7, the universal substrate 500 further comprises the traces 350 covered by the solder mask 330. In the present embodiment, at least one of the first exhaust grooves 340 can be partially overlapped with at least one of the traces 350.

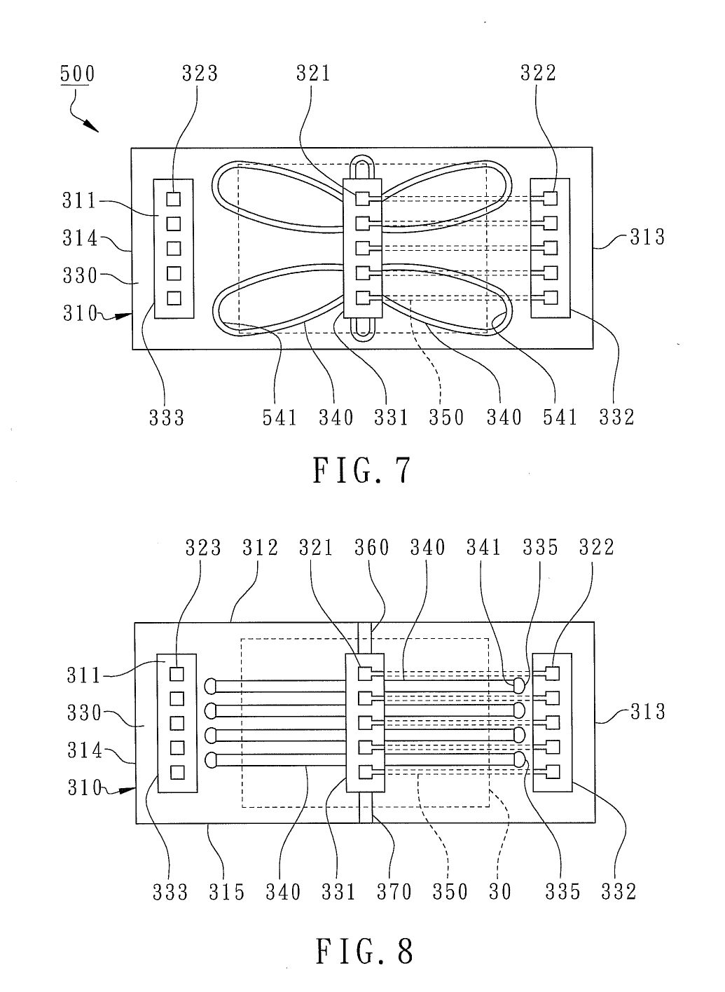

As shown in FIG. 8, one of the variations of the first embodiment is further described. The universal substrate further comprises a plurality of bleeding reservoirs 335 penetrating through the solder mask 330 and connected with the extended ends 341 of the first exhaust grooves 340. The bleeding reservoirs 335 are not overlapped with the traces 350. The shapes of the bleeding reservoirs 335 can be round or rectangular. In a specific embodiment, the bleeding reservoirs 335 have a diameter or a side greater than the width of the first exhaust grooves 340. During die-attaching processes, even if the bleeding goes beyond the extended ends 341 of the first exhaust grooves 340, the bleeding reservoirs 335 can prevent the bleeding from further flooding and contaminations.

Furthermore, the present invention can further be implemented in normal packaging substrates where the solder mask has central openings and peripheral openings. The central opening is formed under the chip covering area where a plurality of exhaust grooves formed on the solder mask without penetrating through the solder mask are connected to the central opening and extended toward the edges of the surface of the substrate core without connecting to the peripheral openings to eliminate the issues of bubbles trapped at the central opening and the issues of peripheral openings contaminated by the bleeding of die-bonding adhesive.

The above description of embodiments of this invention is intended to be illustrative but not limiting. Other embodiments of this invention will be obvious to those skilled in the art in view of the above disclosure.

What is claimed is:

1. A universal substrate for semiconductor packages, primarily comprising:
a substrate core having a surface;
a first row of bonding fingers disposed on the surface of the substrate core;
a second row of bonding fingers disposed on the surface of the substrate core;
a third row of bonding fingers disposed on the surface of the substrate core, wherein the first row of bonding fingers are located between the second row of bonding fingers and the third row of bonding fingers; and
a solder mask formed on the surface of the substrate core, the solder mask having a first opening exposing the first row of bonding fingers, a second opening exposing the second row of bonding fingers, and a third opening exposing the third row of bonding fingers; the solder mask further having a plurality of first exhaust grooves formed on an exposed surface of the solder mask without penetrating through the solder mask;
wherein one end of the first exhaust grooves connects to the first opening, and the other end extends toward a plurality of edges of the surface of the substrate core without connecting to the second opening nor to the third opening.

2. The universal substrate as claimed in claim 1, further comprising a plurality of traces formed on the surface of the substrate core to connect the first row of bonding fingers with the second row of bonding fingers, wherein the solder mask covers the traces.

3. The universal substrate as claimed in claim 2, wherein the solder mask has a non-penetrated thickness from the first exhaust grooves to the substrate core which is not greater than the thickness of the traces, wherein the first exhaust grooves are staggeredly dislocated with the traces without overlapping.

4. The universal substrate as claimed in claim 2, wherein the solder mask has a non-penetrated thickness from the first exhaust grooves to the substrate core which is greater than the thickness of the traces, wherein at least one of the first exhaust grooves is overlapped with at least one of the traces without exposing the traces.

5. The universal substrate as claimed in claim 1, wherein the solder mask further has at least a connecting groove crossed with the first exhaust grooves as a net.

6. The universal substrate as claimed in claim 1, wherein the adjacent extended ends of the adjacent first exhaust grooves are connected to each other to form a U-shape channel of bleeding backflow.

7. The universal substrate as claimed in claim 2, wherein the edges of the surface of the substrate core include a first edge, a second edge, and a third edge, wherein the second edge and the third edge are parallel, the first edge connects to the second edge and to the third edge, wherein the second row of bonding fingers are disposed along the second edge, the third row of bonding fingers along the third edge, and wherein the first row of bonding fingers are configured as a plurality of redistribution fingers.

8. The universal substrate as claimed in claim 7, wherein the solder mask further has at least a second exhaust groove with one end connecting the first opening and the other end extended toward the first edge.

9. The universal substrate as claimed in claim 7, wherein the second opening and the third opening are two closed peripheral openings adjacent to the second edge and to the third edge respectively.

10. The universal substrate as claimed in claim 7, wherein the second opening and the third opening are two open-loop peripheral openings connecting the second edge and the third edge respectively.

11. The universal substrate as claimed in claim 1, further comprising a plurality of bleeding reservoirs penetrating through the solder mask and connected with the extended ends of the first exhaust grooves.

12. A semiconductor package comprising the universal substrate as claimed in claim 1, further comprising:
a chip disposed on the universal substrate to cover the first row of bonding fingers and the first opening, wherein the chip has a plurality of first bonding pads and a plurality of second bonding pads;
a die-bonding adhesive fixing the chip to the solder mask, wherein the die-bonding adhesive fills the first opening and the first exhaust grooves;
a plurality of first bonding wires electrically connecting the first bonding pads of the chip to the second row of bonding fingers; and
a plurality of second bonding wires electrically connecting the second bonding pads of the chip to the third row of bonding fingers.

13. The semiconductor package as claimed in claim 12, wherein the extended ends of the first exhaust grooves extend beyond the chip.

14. The semiconductor package as claimed in claim 12, further comprising an encapsulant formed on the universal substrate to encapsulate the chip, the first bonding wires, and the second bonding wires, wherein the die-bonding adhesive fills a section of the first exhaust grooves under the chip and the encapsulant fills the other section of the first exhaust grooves outside the chip.

15. The semiconductor package as claimed in claim 12, wherein the universal substrate further comprises a plurality of traces formed on the surface of the substrate core to connect the first row of bonding fingers with the second row of bonding fingers, wherein the solder mask covers the traces.

16. A semiconductor package, comprising the universal substrate for semiconductor packages as claimed in claim 1, wherein the semiconductor package further comprising:
a chip disposed on the universal substrate and located between the first row of bonding fingers and the third row of bonding fingers, wherein the chip has a plurality of first bonding pads and a plurality of second bonding pads;
a die-bonding adhesive fixing the chip to the solder mask, wherein the die-bonding adhesive fills the first exhaust grooves;
a plurality of first bonding wires electrically connecting the first bonding pads of the chip to the first row of bonding fingers; and
a plurality of second bonding wires electrically connecting the second bonding pads of the chip to the third row of bonding fingers.

17. The semiconductor package as claimed in claim 16, further comprising an encapsulant formed on the universal substrate to encapsulate the chip, the first bonding wires, and the second bonding wires, wherein the encapsulant fills the first opening.

18. The semiconductor package as claimed in claim 17, further comprising a dummy chip disposed on the universal substrate and located between the first row of bonding fingers and the second row of bonding fingers, wherein the encapsulant further encapsulates the dummy chip.

19. The semiconductor package as claimed in claim 16, wherein the universal substrate further comprises a plurality of traces formed on the surface of the substrate core to connect to the first row of bonding fingers with the second row of bonding fingers, wherein the solder mask covers the traces.

20. A substrate comprising:
a substrate core having a surface;
a plurality of bonding fingers disposed on the surface of the substrate core; and
a solder mask formed on the surface of the substrate core, the solder mask having a central opening and at least a peripheral opening to expose the bonding fingers; the solder mask further having a plurality of exhaust grooves formed on an exposed surface of the solder mask without penetrating through the solder mask; wherein one end of the exhaust grooves connects to the central opening, and the other end extends toward a plurality edges of the surface of the substrate core without connecting to the peripheral opening.
